(19) United States
(12) Patent Application Publication
(10) Pub. No.: US 2026/0230052 A1
(43) Pub. Date: Aug. 6, 2026

(54) MEASUREMENT AND COMPENSATION OF AMPLIFIER INPUT OFFSET

(71) Applicant: Microchip Technology Incorporated, Chandler, AZ (US)

(72) Inventor: Jason M. Sachs, Chandler, AZ (US)

(21) Appl. No.: 19/390,205

(22) Filed: Nov. 14, 2025

Related U.S. Application Data
(60) Provisional application No. 63/752,394, filed on Jan. 31, 2025.

(51) Int. Cl. H03G 3/30; G01R 19/00

(52) U.S. Cl. CPC H03G 3/30; G01R 19/0038; H03G 2201/103

(57) ABSTRACT

An apparatus includes a voltage amplifier and a logic circuit. The voltage amplifier may have selectable gain. The logic circuit may determine a value indicative of input offset of the voltage amplifier based at least partially on one or more reference output signals generated by the voltage amplifier in at least one of the selected gains. The logic circuit may apply a trim setting to the voltage amplifier, the trim setting corresponding to the determined value indicative of input offset.

### CROSS-REFERENCE TO RELATED APPLICATIONS

This application claims the benefit under 35 U.S.C. § 119 (e) of U.S. Provisional Patent Application Ser. No. 63/752,394, filed Jan. 31, 2025, the disclosure of which is hereby incorporated herein in its entirety by this reference.

### FIELD

One or more examples relate, generally, to measuring and compensating for input offset in a circuit, and more specifically, one or more examples relate, generally, to measuring and compensating for input offset of an amplifier.

### BACKGROUND

Amplifiers act as an intermediary between a source and a load to ensure variations in the load's requirements do not affect the source and vice-versa. Amplifiers are utilized in a variety of operational contexts. Minimizing input offset voltage of an amplifier is important to maintain accuracy of the amplified signal.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram depicting a system to measure and compensate for (e.g., reduce, without limitation), input offset of a voltage amplifier, in accordance with one or more examples.

FIG. 2 is a circuit diagram depicting an apparatus to generate an output signal in multiple selectable gains, in accordance with one or more examples.

FIG. 3 is a circuit diagram depicting an apparatus to generate an output signal in multiple selectable gains, in accordance with one or more examples.

FIG. 4 is a block diagram of a system that utilizes one or more reference signals generated, in accordance with one or more examples.

FIG. 5 illustrates an example process to control measurement and compensation of input offset at a voltage amplifier, in accordance with one or more examples.

FIG. 6 illustrates an example process controlling measurement and compensation of input offset at a voltage amplifier, in accordance with one or more examples.

FIG. 7 illustrates an example process to measure input offset of a voltage amplifier, in accordance with one or more examples.

FIG. 8 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

A voltage amplifier may isolate an input (of the amplifier) from the output (of the amplifier) to prevent loading effects, provide impedance matching between circuits, and/or deliver a stable output voltage, even under varying load conditions.

Input offset is the amount of additional input voltage required, in addition to the ideal input voltage, to ensure an amplifier with inherent imperfections produces a target output voltage. Examples of inherent imperfections include, but are not limited to, transistor-pair mismatch and/or internal bias currents.

In some cases, an amplifier circuit may include multiple amplifiers (respectively an “input stage”) whose combined input range covers the desired input range of the amplifier circuit. Respective input stages may exhibit the same or different input offset. So, amount of input offset may change depending on the specific portion of the input range.

One or more examples relate, generally, to a method and system to measure and compensate for (e.g., reduce, without limitation) input offset in a circuit, and more specifically, input offset of an amplifier.

Such functionality may be desirable in applications requiring precise voltage references, such as analog-to-digital converters (ADCs), sensor interfaces, or other signal processing systems, without limitation.

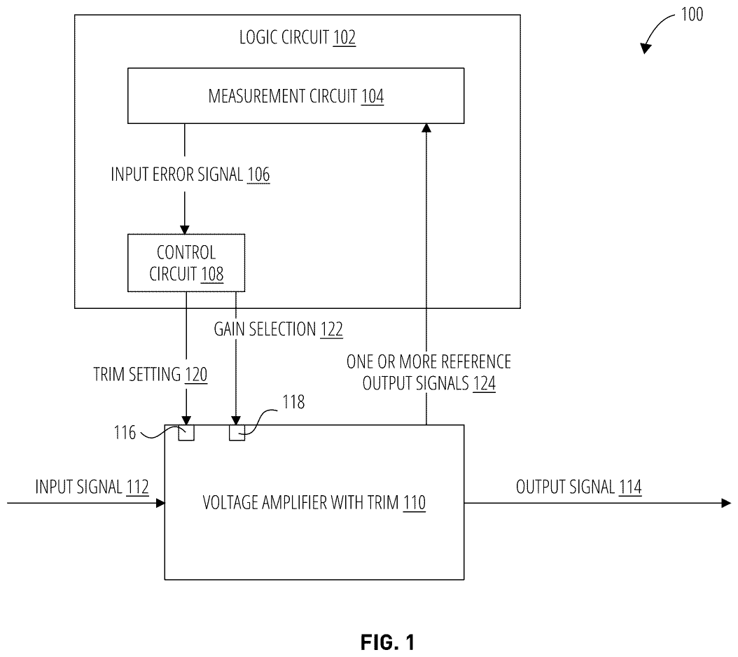

FIG. 1 is a block diagram depicting a system 100 to measure and compensate for (e.g., reduce, without limitation) input offset of a voltage amplifier, in accordance with one or more examples.

Generally speaking, system 100 detects (e.g., dynamically detects, without limitation) and reduces input offset exhibited by the output signal of a voltage amplifier. By way of non-limiting example, reducing input offset ensures that output signal 114 suitably matches input signal 112, even in the presence of intrinsic amplifier imperfections, such as mismatched components or environmental changes, without limitation.

In one or more examples, system 100 reduces input offset by producing reference output signals that are indicative of the input offset of the voltage amplifier, measuring input offset (or values indicative thereof) based on the reference output signals, determining trim settings (e.g., trim settings configured to reduce input offset, without limitation) based on the measured input offset, and applying trim to the voltage amplifier according to the determined trim settings and thereby reduce input offset of the voltage amplifier.

Here, “trim” generally refers to an adjustment to a parameter of a circuit (e.g., an amplifier such as voltage amplifier with trim 110, without limitation) to ensure a target performance or specification. In the case of op-amp based amplifiers, examples of a trimming mechanism include, but are not limited to, mechanisms for adjusting transistor bias currents, such as a digitally-controlled current source, a variable resistor, or a digital-to-analog-converter (DAC).

System 100 includes a logic circuit 102 and a voltage amplifier with trim 110. Logic circuit 102 includes measurement circuit 104 and a control circuit 108. The voltage amplifier with trim 110 includes a trim input 116 and a gain-select input 118.

Voltage amplifier with trim 110 generates a stable, accurate, and isolated (i.e., buffered) output signal 114 at least partially based on input signal 112. As non-limiting example, input signal 112 may originate from a source that requires buffering to prevent signal degradation due to load effects or impedance mismatches. As a non-limiting example, an output signal 114 generated by voltage amplifier with trim 110 may be a suitable reproduction of input signal 112 that can serve downstream circuits or systems, ensuring the integrity and stability of the signal during further processing.

Voltage amplifier with trim 110 may adjust the relationship between its input and output signals based on a gain selected via gain selection signal 122 (“gain selection 122”), which is applied to the amplifier's gain-select input 118, and a trim set via trim setting signal (“trim setting 120”), as discussed below.

Voltage amplifier with trim 110 includes trim input 116 and gain-select input 118. Trim input 116 is a physical or logical connection (e.g., interface, without limitation) for receiving trim values. In one or more examples, trim values received via trim input 116 may be utilized to adjust internal parameters (e.g., bias current, feedback resistance, or other parameters that influence input offset, without limitation) of voltage amplifier with trim 110. As discussed herein, such adjustments may be configured to reduce input offset at voltage amplifier with trim 110.

Gain-select input 118 is a physical or logical connection (e.g., interface, without limitation) utilized to receive and/or provide values of gain selection 122 (gain-selection values). The gain selection 122 determines the operational gain of the amplifier, which determines how input signal 112 is amplified (e.g., according to baseline gain, unity gain, amplified gain, or offset-amplified gain, without limitation). The selectable gains are predefined configurations of voltage amplifier with trim 110, respectively corresponding to a different level or type of amplification. Non-limiting examples of gains include at least: a baseline gain where the gain K1 of the input signal 112 and input offset is such that an output signal 114 matches a baseline reference signal, or an offset-amplified gain where a gain K1 of the input signal 112 remains the same as in the baseline gain case and a gain K2 of the input offset increases. In the case where the output signal 114 is an output voltage, the output voltage Vout in the baseline gain case may be expressed as Vout=K1×(Vin+Voffset). The output voltage Vout in the offset-amplified gain case may be expressed as Vout=K1×Vin+K2×Voffset, where K2>K1.

In one or more examples, logic circuit 102 includes measurement and control capabilities to enable input offset determination and compensation for voltage amplifier with trim 110. Logic circuit 102 receives various reference output signals 124 generated by voltage amplifier with trim 110 in various gains controlled by logic circuit 102 via gain selection 122. Logic circuit 102 processes the various reference output signals 124 to extract information about the behavior of voltage amplifier with trim 110 and applies corrective adjustments via trim setting 120, which are configured to reduce input offset at voltage amplifier with trim 110.

In one or more examples, measurement circuit 104 may determine (e.g., estimate, without limitation) an input offset of voltage amplifier with trim 110 based on various reference signals. For example, based on predetermined voltage value that represents a known reference (e.g., predetermined values that represent expected ideal values or internally stored calibration data, without limitation), or reference output signals that serve as indicators of the behavior of voltage amplifier with trim 110 in various gain configurations. In one or more examples, the one or more reference output signals 124 provided by voltage amplifier with trim 110 may include a baseline reference output and an offset-amplified reference output. Additionally, or alternatively, the one or more reference output signals 124 provided by voltage amplifier with trim 110 may include first and second offset-amplified reference outputs. Additional reference output signals may be utilized without exceeding the scope of this disclosure.

A baseline reference output may be or include an instance of the output signal 114 produced by voltage amplifier with trim 110 in baseline gain. An offset-amplified reference output reflects the behavior of the voltage amplifier with trim 110 when it operates with a gain that amplifies the input offset. The offset-amplified reference output may be or include an instance of the output signal 114 produced by the voltage amplifier with trim 110 in amplified offset gain.

Measurement circuit 104 receives one or more reference output signals 124, including a baseline reference output and an offset-amplified reference output, and processes these to determine the input error signal 106, which is provided to control circuit 108. Measurement circuit 104 determines input error signal 106 at least partially based on the difference between processed reference output signals of one or more reference output signals 124, and input error signal 106 is indicative of the input offset of voltage amplifier with trim 110. As a non-limiting example, a relationship between input error signal 106 (or changes in input error signal 106) and input offset (or changes in input offset) of voltage amplifier with trim 110, may be proportional or defined by a known mathematical function.

The baseline reference output provides a baseline signal for comparison, which includes any inherent offset of the voltage amplifier with trim 110. The offset-amplified reference output magnifies the input offset for finer measurement and characterization by the measurement circuit 104. The gain is deliberately increased to amplify the offset while retaining the relationship to the input signal. Together, these outputs allow the measurement circuit 104 to determine the magnitude and polarity of the offset and distinguish the offset from other potential sources of error or signal variation. In one or more examples, the input signal 112 may be static or at least slowly-varying, so that it is possible to measure the difference between the baseline gain and higher-gain variants, and know that it is dependent primarily on the offset voltage.

In some cases, direct measurement of the input offset may not be feasible, and so the circuit gain K and the corresponding measured voltage difference for the trim settings may be used to inform determination of trim settings 120.

In one or more examples, measurement circuit 104 may determine input error signal 106 at least partially based on differences between respective one or more reference output signals 124. Measurement circuit 104 determines the difference between respective reference output signals 124, chooses trim settings 120 based on the difference, and estimates values for input error signal 106 based on the chosen trim settings, and provides the estimated values to control circuit 108.

By way of specific, non-limiting example, assume a trim setting of TRIM=3 produces an input voltage offset of +1.1 mV, and a trim setting of TRIM=4 produces an input voltage offset of −0.8 mV. It is known (e.g., by control circuit 108) that the nominal circuit gain K=240, and that the circuit gain K*input offset=measured voltage difference=+264 mV at TRIM=3 (i.e., TRIM=3 produced an error signal 106 of +264 mV) and −192 mV at TRIM=4 (i.e., TRIM=4 produced an error signal 106 of −192 mV). In this case, because the trim response is generally monotonic and continuous, and because two consecutive digital trim settings (TRIM=3 and TRIM=4) produce error signals of opposite polarity, the system is said to have bracketed the root—i.e., the ideal trim setting that would produce zero offset lies between the two settings. As the available trim resolution does not allow setting intermediate values, control circuit 108 may choose the trim setting 120 that produces the smaller magnitude error signal/measured voltage difference, here TRIM=4 (−192 mV<264 mV). This bracketing approach ensures that, even without direct access to a zero-offset setting, the system can confidently select the closest achievable trim setting by identifying consecutive trim settings with error signals of opposite polarity.

Actual input offset can be affected by other signal errors (e.g., noise, offset drift, without limitation), nonlinearity, and differences between the unknown real gain K and the assumed nominal gain K. So, in some examples, control circuit 108 may also estimate values for the input offset based on knowledge of the nominal value of gain K, as a non-limiting example: by dividing the error signal by the nominal value of gain K.

Additionally, or alternatively to providing error signal 106 that is indicative of input offset, in some examples, measurement circuit 104 may provide input offset directly to control circuit 108 (e.g., provide input offset as the error signal 106, without limitation). As a non-limiting example, measurement circuit 104 may determine (e.g., estimate, without limitation) an input offset of voltage amplifier with trim 110 as a function of the one or more reference output signals 124 and/or measured voltage differences, and provide the determined value indicative of input offset to the control circuit 108.

Control circuit 108 is a core logic or microcontroller unit that manages the input offset measurement and compensation process. Control circuit 108 may set the gain of the voltage amplifier with trim 110 by controlling the gain-select input 118 of voltage amplifier with trim 110 to toggle between: baseline gain to produce baseline input offset measurement and offset-amplified gain to magnify the input offset to allow precise measurement. The control circuit 108 receives the input error signal 106 from measurement circuit 104, which indicates the magnitude and polarity of the input offset to be corrected. Based on the input error signal 106, the control circuit 108 generates a trim setting 120 configured to adjust internal parameters of the voltage amplifier with trim 110 and thereby reduces input offset of voltage amplifier with trim 110. In one or more examples, the measurement and compensation processes may be an iterative process where the input offset is progressively reduced over multiple cycles of measurement and compensation, or as a single-pass operation.

In one or more examples, control circuit 108 and measurement circuit 104 may be “on-chip” with voltage amplifier with trim 110. On-chip integration ensures that the internal material in a single die is internally well-matched: within nearby sections of that die, the temperature is largely constant, as are the operational parameters of the material. So, if resistors go up due to temperature changes, the on-chip resistors tend to vary together in the same way, and the end effect on circuit function largely cancels out.

In the case of precision circuits, thermoelectric voltages may be considered. If two dissimilar metals are used in a system with a temperature gradient, they produce a parasitic voltage that can increase the voltage error in the overall circuit function. By using an on-chip circuit, the temperature gradient can be minimized and the material mismatch of metals can be minimized, to keep thermoelectric voltages small. Off-chip circuits have larger temperature gradients and usually involve some kind of change in the metal material; circuit boards will use copper for the conductor, whereas the metal in an IC die may be aluminum or copper and the bond wires between the IC die and the lead frame may be aluminum, copper, silver, or gold. These differences in material create more opportunities for thermoelectric voltages.

Further, on-chip integration ensures that the measurement, control, and trimming processes occur within a single semiconductor chip or IC, allowing for tighter coupling, reduced parasitic effects, and lower noise compared to ‘off-chip’ designs. In typical ‘off-chip’ implementations, circuits are housed separately, requiring external connections that introduce additional resistance, capacitance, and potential for electromagnetic interference, which can degrade signal fidelity and offset measurement accuracy. On-chip integration enables shorter signal paths, improving precision and enabling real-time measurement and compensation of the input offset. It also reduces the physical footprint of the system, lowers material costs by eliminating external components, and enhances reliability by minimizing the number of external connections susceptible to mechanical failure or environmental factors. Furthermore, on-chip systems are better suited for dynamic calibration processes, as the close proximity of the components allows faster and more efficient feedback loops compared to off-chip alternatives.

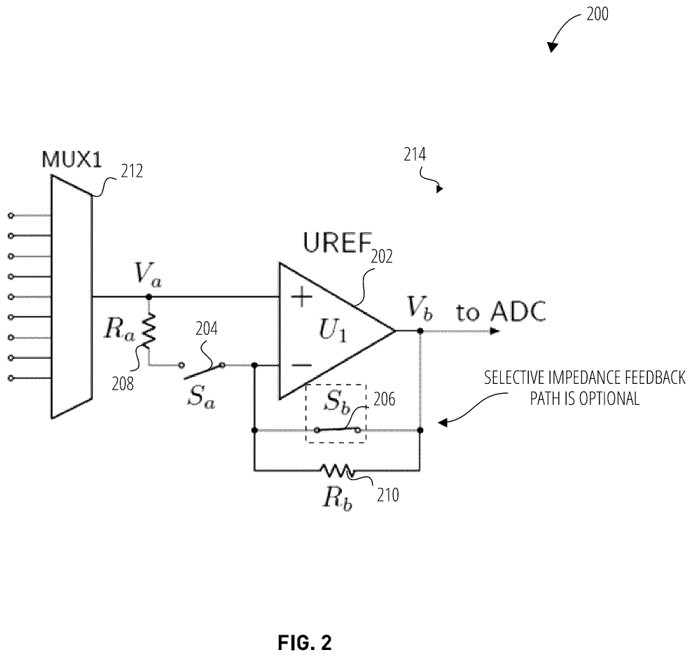

FIG. 2 is a circuit diagram depicting an apparatus 200 to generate an output signal in multiple selectable gains, in accordance with one or more examples. Apparatus 200 may also be referred to as reference signal generation circuit 200.

Reference signal generation circuit 200 includes a voltage amplifier 214 and a multiplexer (MUX) 212. Voltage amplifier 214 includes op-amp 202, first switch 204, optional second switch 206, first resistor 208, and second resistor 210.

Reference signal generation circuit 200 generates a stable reference signal (Vb) from a selected input signal (Va) received via MUX 212. Reference signal generation circuit 200 may provide a reference voltage (UREF) for downstream components (not depicted), such as an analog-to-digital converter (ADC), without limitation.

This circuit integrates first resistor 208 and second resistor 210, switches 204 and 206, and op-amp 202 to facilitate dynamic gain adjustment and produce multiple reference outputs, as discussed below.

In one or more examples, op-amp 202 is an Integrated Circuit (IC) op-amp (implemented with complementary metal-oxide-semiconductor (CMOS) technology, Bipolar Junction-Transistor (BJT) technology, or other transistor technologies). Intrinsic offset in an IC op-amp may be caused by mismatches and imperfections in the internal components of the op-amp 202.

For example, op-amps built using transistor technologies, in differential pairs (e.g., in the input stage, without limitation) should be perfectly matched. However, in practice, variations in threshold voltage (Vₜₕ), transconductance (gₘ), and physical dimensions during manufacturing lead to small mismatches in circuit behavior, causing a nonzero input offset voltage. Further, an IC op-amp's input transistors are typically biased by current sources. Any mismatch in the bias currents due to variations in the current source transistors or resistors adds to input offset. Further still, intrinsic characteristics of the transistors (e.g., threshold voltage, mobility, without limitation) depend on temperature. Uneven heating within the chip or temperature gradients can exacerbate input offsets. Further still, variability in semiconductor manufacturing processes introduces inconsistencies in the transistors and resistors used in an op-amp's design, and such small variations manifest as systematic input offset that cannot be eliminated without compensation techniques like trimming.

In the voltage amplifier 214, activating the optional second switch 206 (e.g., via control signal S_{b}) and deactivating the first switch 204 (e.g., via control signal Sₐ) bypasses the feedback resistor (second resistor 210), establishing a direct feedback loop for unity gain operation.

Notably, optional second switch 206 and the selective impedance feedback path that includes it are optionally included to reduce performance errors in various configurations of voltage amplifier 214 (e.g., baseline gain, unity gain, offset-amplified gain, without limitation). Conversely, activating the first switch 204 (e.g., via control signal Sₐ) and deactivating the optional second switch 206 (e.g., via control signal S_{b}) enables the feedback resistor (second resistor 210), configuring the circuit for offset-amplified gain.

The gain of the circuit is expressed as 1+K, where

$$K = \frac{Rb}{Ra} .$$

In a contemplated operation, reference signal generation circuit 200 receives a signal via MUX 212 (e.g., from an adjustable input voltage source (e.g., a DAC, without limitation), resistor divider, or bandgap reference, without limitation) to set the UREF input Va and measures output voltages Vb₁ and Vb₂ in unity gain and offset-amplified gain, respectively. The estimated input offset may be determined by (Vb₁−Vb₂)/(1+K), and the determined estimated input offset may be compensated for an input range corresponding to the input voltage Va (e.g., via firmware, without limitation). In the case of voltage amplifier 214 having multiple input stages (corresponding to Va₁, Va₂, Va₃, . . . . Vaₙ), respective estimated input offsets may be determined across the full input range of voltage amplifier 214 (i.e., a totality of the input stages of voltage amplifier 214) and respectively compensated for.

The depiction of mechanical switches in FIG. 2 is only illustrative and is not intended to suggest or limit this disclosure to the use of mechanical switches in an actual implementation. The switches are depicted in this manner as a convenient way to represent on/off (open or closed) functionality. Any suitable switch technology, including, but not limited to, transistor-based switches (e.g., MOSFETs or BJTs, without limitation), may be used in the implementation of this circuit without exceeding the scope.

Some examples may relate, generally, to a non-unity gain configuration of a voltage amplifier. A voltage amplifier in the non-unity gain configuration amplifies an input signal by a specific factor other than 1, determined by various gain setting components.

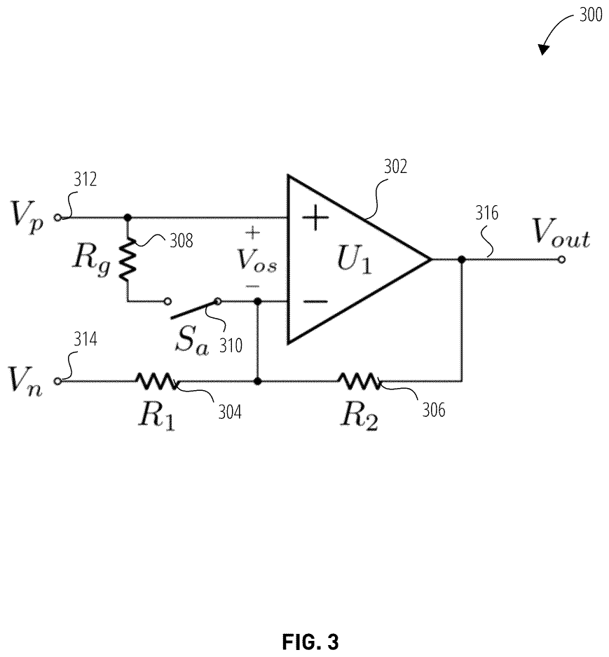

FIG. 3 is a circuit diagram depicting an apparatus 300 to generate an output signal in multiple selectable gains, in accordance with one or more examples. Apparatus 300 may also be referred to as voltage amplifier 300, and may be used, as a non-limiting example, in a reference signal generation circuit such as reference signal generation circuit 200.

In an inverting or non-inverting configuration, the gain is set by the first gain setting resistor 304 (having resistance R₁) and the second gain setting resistor 306 (having resistance R₂), for example:

In an inverting configuration, the positive node 312 is a reference voltage (Vₚ), and the negative node 314 is the input voltage (Vₙ), with a gain of −R₂/R₁.

In a non-inverting configuration, the negative node 314 is a reference voltage (Vₙ), and the positive node 312 is the input voltage (Vₚ), with a gain of 1+R₂/R₁.

In both configurations, without the gain-switching resistor 308 (having resistance R_{g}), the input offset voltage (Vₒₛ) is amplified by a gain equal to the offset gain of 1+R₂/R₁.

The gain-switching resistor 308 and the switch 310 allow increasing the offset gain by a factor of R₂/R_{g} when switch 310 is closed. This adjustment does not affect the circuit gains of the input voltages at nodes 312 or 314.

For example, suppose R₂=30 kΩ and R₁=10 kΩ:

In an inverting configuration, this corresponds to a gain of:

$$Gain = - \frac{30 k Ω}{10 k Ω} = - 3$$

In a non-inverting configuration, this corresponds to a gain of:

$$Gain = 1 + \frac{30 k Ω}{10 k Ω} = 4$$

In both cases, the input offset voltage gain is:

$$Offset Gain = - ( 1 + \frac{30 k Ω}{10 k Ω} ) = - 4$$

If R_{g}=2 kΩ, the offset gain can be increased by a factor of R₂/R_{g}=30 kΩ/2 kΩ=15, which results in an offset gain of Offset Gain=−4+(−15)=−19, when switch 310 is closed.

This configuration enables a comparison of the output voltages at the output node 316 in the two states (switch 310 open or closed), allowing the trimming of the input offset to minimize errors.

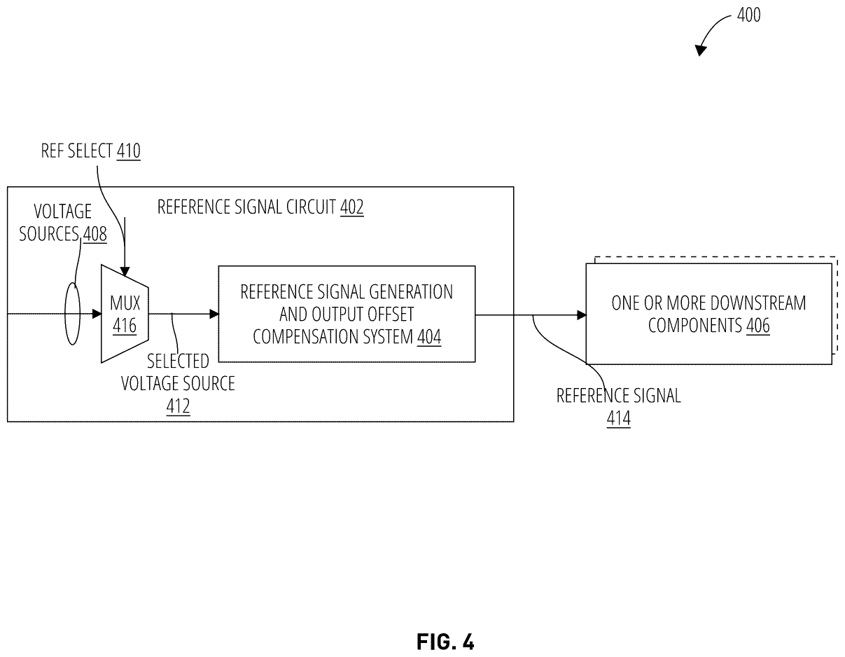

FIG. 4 is a block diagram of a system 400 that utilizes one or more reference signals generated in accordance with one or more examples.

System 400 includes a reference signal circuit 402 that provides one or more reference signals 414 for one or more downstream components 406. Reference signal circuit 402 includes a reference signal generation and output offset compensation system 404, which may be, as a non-limiting example, a system 100 of FIG. 1, and a MUX 416 to provide, in response to reference select signal 410 (“ref select 410”), selected ones of voltage sources 408 (provided as selected voltage source 412) to reference signal generation and output offset compensation system 404. As non-limiting examples, voltage sources 408 may be DAC outputs, bandgap outputs, or voltage divider outputs.

Generally speaking, reference signal circuit 402 buffers the selected voltage source 412 using the reference signal generation and output offset compensation system 404 to ensure high stability, accuracy, and offset correction. Reference signal circuit 402 outputs the reference signal 414 to one or more downstream components 406, such as analog-to-digital-converters (ADCs) or other circuits that rely on a stable reference voltage.

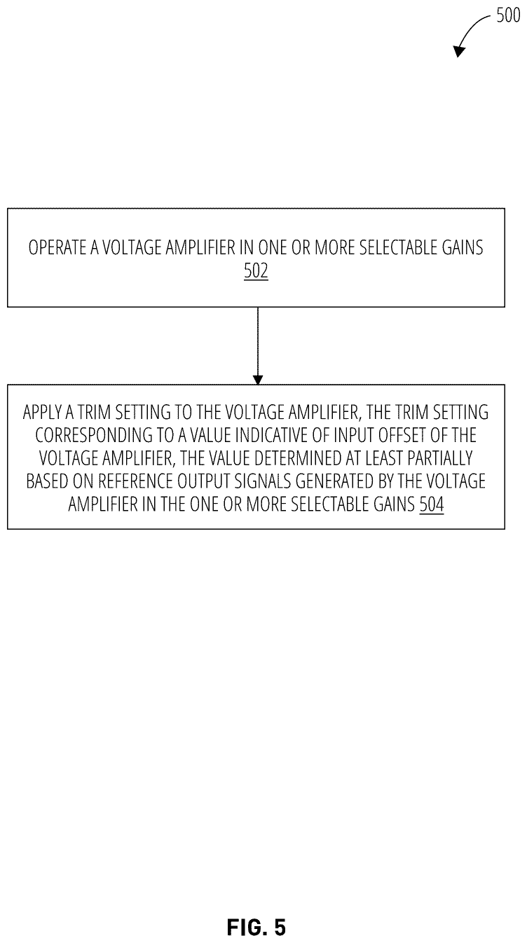

FIG. 5 illustrates an example process 500 to control measurement and compensation of input offset at a voltage amplifier, in accordance with one or more examples.

Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. One or more operations of process 500 may be performed, as non-limiting examples, by logic circuit 102, measurement circuit 104, control circuit 108, system 100, reference signal generation and output offset compensation system 404, or reference signal circuit 402.

According to one or more examples, the method includes operating a voltage amplifier in one or more selectable gains, at operation 502. Examples of selectable gain include: a unity gain where the output voltage equals the input voltage, effectively serving as a buffer, a baseline gain where the output voltage equals a baseline voltage, and an offset-amplified gain where the amplifier magnifies the inherent input offset for easier measurement. In various examples, gain may be selected by controlling external or internal elements such as: switches in a feedback network, digital or analog control signals sent to the amplifier, or programmable logic that configures the voltage amplifier dynamically.

According to one or more examples, the method includes applying a trim setting to the voltage amplifier, at operation 504. The trim setting corresponds to the value indicative of input offset determined at least partially based on reference output signals respectively generated by the voltage amplifier while in the one or more gains.

As a non-limiting example, the trim setting may be determined at least partially based on the value indicative of input offset. The trim setting is intended to compensate for (e.g., reduce, without limitation) input offset by adjusting various characteristics of the voltage amplifier. In some examples, a linear relationship or mapping may be applied to determine the trim setting based on the value indicative of input offset. In other examples, a non-linear relationship or mapping may be applied (e.g., utilizing a calibration table or algorithm, without limitation).

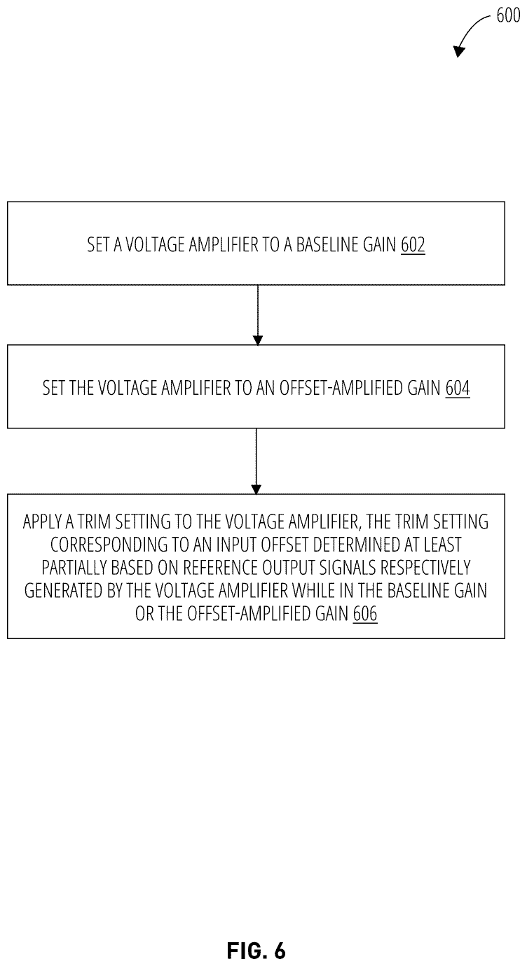

FIG. 6 illustrates an example process 600 controlling measurement and compensation of input offset at a voltage amplifier, in accordance with one or more examples. Although the example process 600 depicts a particular sequence of operations, the sequence may be altered without departing from the scope of the present disclosure. For example, some of the operations depicted may be performed in parallel or in a different sequence that does not materially affect the function of process 600. In other examples, different components of an example device or system that implements process 600 may perform functions at substantially the same time or in a specific sequence. One or more operations of process 600 may be performed, as non-limiting examples, by logic circuit 102, measurement circuit 104, control circuit 108, system 100, reference signal generation and output offset compensation system 404, or reference signal circuit 402.

According to one or more examples, process 600 may include setting a voltage amplifier to a baseline gain at operation 602. While in baseline gain the voltage amplifier can generate a baseline reference output.

According to one or more examples, process 600 may include setting the voltage amplifier to an offset-amplified gain at operation 604. While in the offset-amplified gain the voltage amplifier can generate an offset-amplified reference output.

According to one or more examples, process 600 may include applying a trim setting to the voltage amplifier, at operation 606. The trim setting corresponds to an input offset determined at least partially based on reference output signals respectively generated by the voltage amplifier while in the baseline gain or while in the offset-amplified gain. There is a relationship between the trim setting and the input offset. As a non-limiting example, the trim setting is determined at least partially based on the measured input offset. It is intended to compensate for (e.g., reduce) input offset by adjusting various characteristics of the voltage amplifier. In some examples, a linear relationship or mapping may be applied to determine the trim setting based on the input offset. In other examples, a non-linear relationship or mapping may be applied (e.g., utilizing a calibration table or algorithm, without limitation) to determine the trim setting.

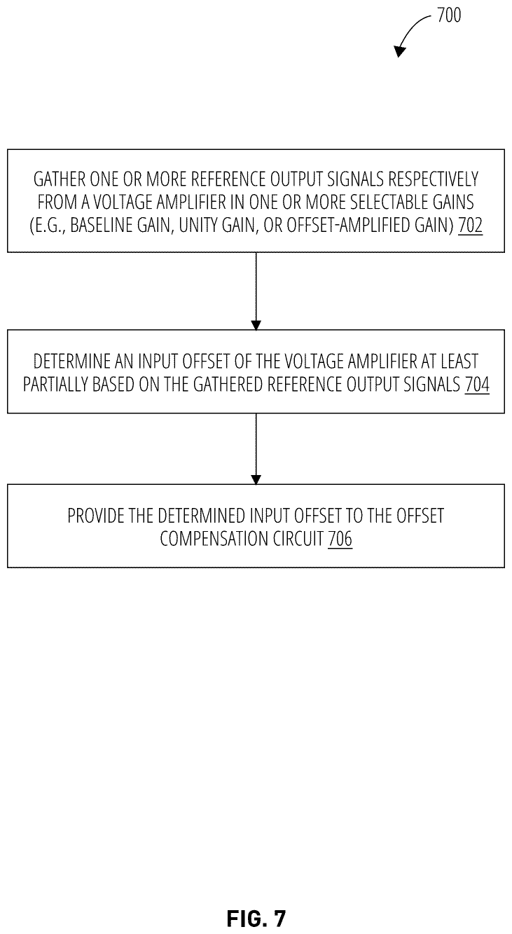

FIG. 7 illustrates an example process 700 to measure input offset of a voltage amplifier, in accordance with one or more examples. Although the example process 700 depicts a particular sequence of operations, the sequence may be altered without departing from the scope of the present disclosure. For example, some of the operations depicted may be performed in parallel or in a different sequence that does not materially affect the function of process 700. In other examples, different components of an example device or system that implements the process 700 may perform functions at substantially the same time or in a specific sequence.

According to one or more examples, process 700 may include gathering one or more reference output signals respectively from a voltage amplifier in one or more gains (e.g., baseline gain or offset-amplified gain, without limitation), at operation 702. The gathered reference output signals may include a baseline reference output and an offset-amplified reference output.

According to one or more examples, process 700 may include determining an input offset (or value indicative thereof) of the voltage amplifier at least partially based on the gathered reference output signals at operation 704. In one or more example, a residual input offset may be determined utilizing the expression for estimated input offset, (V1−V2)/(1+K), discussed above, and the residual offset utilized to determine the input offset.

According to one or more examples, process 700 may include providing the determined input offset (or value indicative thereof) to the offset compensation circuit at operation 706. In one or more examples, a compensation circuit may be a control circuit (e.g., logic circuit 102 or control circuit 108, without limitation).

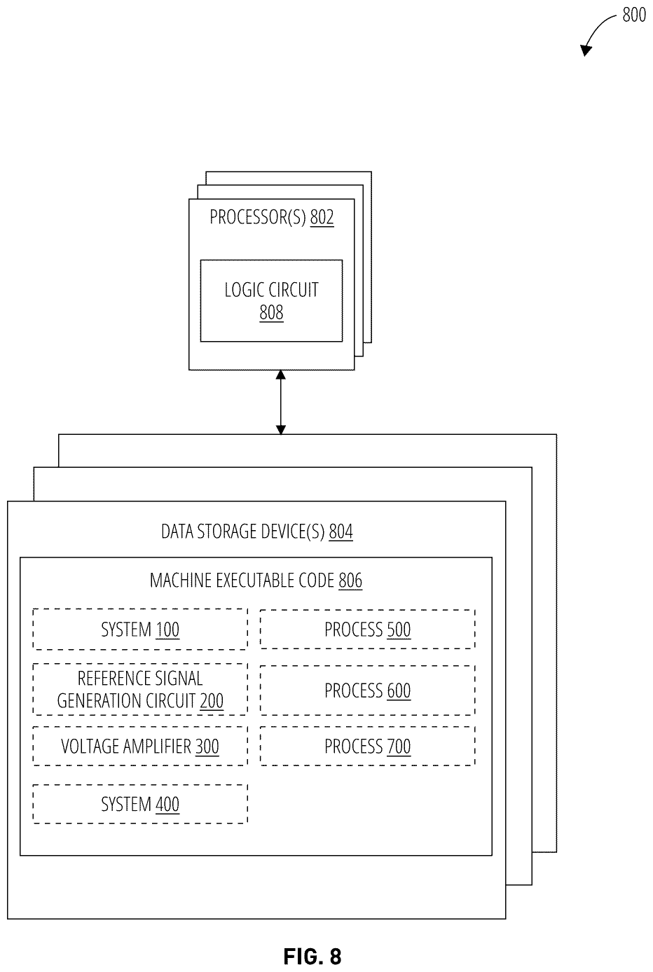

It will be appreciated by those of ordinary skill in the art that functional elements of examples disclosed herein (e.g., functions, operations, acts, processes, or methods) may be implemented in any suitable hardware, software, firmware, or combinations thereof. FIG. 8 illustrates non-limiting examples of implementations of functional elements disclosed herein. In some examples, some or all portions of the functional elements disclosed herein may be performed by hardware capable of carrying out the functional elements.

FIG. 8 is a block diagram of a circuitry 800 that, in some examples, may be used to implement various functions, operations, acts, processes, or methods disclosed herein. The circuitry 800 includes one or more processors 802 (sometimes referred to herein as “processors 802”) operably coupled to one or more data storage devices 804 (sometimes referred to herein as “storage 804”). The storage 804 includes machine executable code 806 stored thereon and the processors 802 include logic circuit 808. The machine executable code 806 includes information describing functional elements that may be implemented by (e.g., performed by) the logic circuit 808. The logic circuit 808 is adapted to implement (e.g., perform) the functional elements described by the machine executable code 806. The circuitry 800, when executing the functional elements described by the machine executable code 806, should be considered as special purpose hardware for carrying out functional elements disclosed herein. In one or more examples, the processors 802 may perform the functional elements described by the machine executable code 806 sequentially, concurrently (e.g., on one or more different hardware platforms), or in one or more parallel process streams.

When implemented by logic circuit 808 of the processors 802, the machine executable code 806 adapts the processors 802 to perform operations of examples disclosed herein. By way of non-limiting example, the machine executable code 806 may adapt the processors 802 to perform some or a totality of operations of one or more of: process 500, process 600, or process 700.

Also by way of non-limiting example, the machine executable code 806 may adapt the processors 802 to perform some or a totality of features, functions, or operations disclosed herein for one or more of: system 100, reference signal generation circuit 200, or system 400. More specifically, features, functions, or operations disclosed herein for one or more of: logic circuit 102, measurement circuit 104, control circuit 108, voltage amplifier with trim 110, trim input 116, or gain-select input 118 of FIG. 1; op-amp 202, first switch 204, optional second switch 206, first resistor 208, second resistor 210, or MUX 212 of FIG. 2; an op-amp 302, a first gain setting resistor 304, a second gain setting resistor 306, a gain-switching resistor 308, a switch 310, a positive node 312, a negative node 314, and an output node 316 of voltage amplifier 300 of FIG. 3; or reference signal circuit 402, reference signal generation and output offset compensation system 404, one or more downstream components 406, or MUX 416 of FIG. 4.

The processors 802 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 802, including a general-purpose processor, is considered a special-purpose computer at least while the general-purpose computer executes functional elements corresponding to the machine executable code 806 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 802 may include any conventional processor, controller, microcontroller, or state-machine. An FPGA or other PLD of the processors 802 may be configured (e.g., programmed, without limitation) with configuration data to perform functions disclosed herein, or, additionally or alternatively, may be capable of being configured or re-configured (e.g., programmable, or re-programmable, without limitation) with configuration data to perform functions disclosed herein. The processors 802 may also be implemented as a combination of computing devices, such as a combination of a DSP and a microprocessor, a plurality of microprocessors, one or more microprocessors in conjunction with a DSP core, or any other such configuration.

In one or more examples, the storage 804 includes volatile data storage (e.g., random-access memory (RAM), static RAM (SRAM), without limitation), non-volatile data storage (e.g., Flash memory, a hard disc drive, a solid state drive, erasable programmable read-only memory (EPROM), without limitation). In some examples, the processors 802 and the storage 804 may be implemented into a single device (e.g., a semiconductor device product, a system on chip (SOC), without limitation). In some examples, the processors 802 and the storage 804 may be implemented into separate devices.

In one or more examples, the machine executable code 806 may include computer-readable instructions (e.g., software code, firmware code). By way of non-limiting example, the computer-readable instructions may be stored by the storage 804, accessed directly by the processors 802, and executed by the processors 802 using at least the logic circuit 808. Also by way of non-limiting example, the computer-readable instructions may be stored on the storage 804, transferred to a memory device (not shown) for execution, and executed by the processors 802 using at least the logic circuit 808. Processors 802 or logic circuit 808 thereof may be coupled to such a memory device or include such a memory device (e.g., a configuration memory cell, without limitation). Accordingly, in some examples, the logic circuit 808 includes electrically configurable logic circuit 808.

In one or more examples, the machine executable code 806 may describe hardware (e.g., circuitry) to be implemented in the logic circuit 808 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG®, SYSTEM VERILOG™ or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 808 may be described in an RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine executable code 806 may include an HDL, an RTL, a GL description, a mask level description, other hardware description, or any combination thereof.

In examples where the machine executable code 806 includes a hardware description (at any level of abstraction), a system (not shown, but including the storage 804) implements the hardware description described by the machine executable code 806. By way of non-limiting example, the processors 802 may include a programmable logic device (e.g., an FPGA or a PLC, without limitation) and the logic circuit 808 may be electrically controlled (e.g., via configuration data, without limitation) to implement circuitry corresponding to the hardware description into the logic circuit 808. Also by way of non-limiting example, the logic circuit 808 may include hard-wired logic manufactured by a manufacturing system (not shown, but including the storage 804) according to the hardware description of the machine executable code 806.

Regardless of whether the machine executable code 806 includes computer-readable instructions or a hardware description, the logic circuit 808 is adapted to perform the functional elements described by the machine executable code 806 when implementing the functional elements of the machine executable code 806. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a voltage amplifier having selectable gain; and a logic circuit to: determine a value indicative of input offset of the voltage amplifier based at least partially on one or more reference output signals generated by the voltage amplifier in at least one of the selected gains; and apply a trim setting to the voltage amplifier, the trim setting corresponding to the determined value indicative of input offset.

Example 2: The apparatus according to Example 1, wherein the voltage amplifier includes an input to receive the trim setting applied by the logic circuit.

Example 3: The apparatus according to Examples 1 and 2, wherein the logic circuit to determine the value indicative of the input offset by processing reference output signals generated by the voltage amplifier in two or more offset-amplified gains.

Example 4: The apparatus according to any of Examples 1 to 3, wherein the logic circuit to determine the value indicative of the input offset by comparing a reference output signal generated in a baseline gain with a reference output signal generated in an offset-amplified gain.

Example 5: The apparatus according to any of Examples 1 to 4, wherein the baseline gain is a unity gain.

Example 6: The apparatus according to any of Examples 1 to 5, wherein the baseline gain is an amplified gain.

Example 7: The apparatus according to any of Examples 1 to 6, wherein the logic circuit to determine the value indicative of the input offset at least partially based on a comparison of a predetermined value to a reference output signal generated by the voltage amplifier in an offset-amplified gain.

Example 8: The apparatus according to any of Examples 1 to 7, wherein the predetermined value represents a target output voltage for a given input voltage.

Example 9: The apparatus according to any of Examples 1 to 8, wherein the logic circuit is on-chip with the voltage amplifier.

Example 10: The apparatus according to any of Examples 1 to 9, wherein the voltage amplifier comprises: a switch; a resistor network operatively coupled to the switch; and an op-amp alternately operable in a baseline gain and an offset-amplified gain responsive to a state of the switch; wherein the logic circuit to: set the switch in a first state to place the voltage amplifier in the offset-amplified gain; and set the switch in a second state to place the voltage amplifier in the baseline gain, the second state different than the first state.

Example 11: The apparatus according to any of Examples 1 to 10, wherein the voltage amplifier comprises: a feedback network comprising a first switch and an optional second switch; a resistor network operatively coupled to the first switch and the optional second switch; and an op-amp operable in a baseline gain and an offset-amplified gain responsive to a state of the feedback network, wherein the logic circuit to: activate the first switch and deactivate the optional second switch to place the voltage amplifier in the offset-amplified gain; and deactivate the first switch and activate the optional second switch to place the voltage amplifier in the baseline gain.

Example 12: The apparatus according to any of Examples 1 to 11, wherein the op-amp is an integrated circuit (IC) op-amp.

Example 13: The apparatus according to any of Examples 1 to 12, wherein the logic circuit determines the trim setting to reduce a difference between an output signal of the voltage amplifier and a target value.

Example 14: A method, comprising: operating a voltage amplifier in one or more selectable gains; and applying a trim setting to the voltage amplifier, the trim setting corresponding to a value indicative of input offset of the voltage amplifier, the value determined at least partially based on reference output signals generated by the voltage amplifier in the one or more selectable gains.

Example 15: The method according to Example 14, comprising: determining the value indicative of input offset of the voltage amplifier at least partially based on one or more of the reference output signals generated by the voltage amplifier in one or more selectable gains.

Example 16: The method according to Examples 14 and 15, wherein determining the value indicative of the input offset comprises comparing a predetermined value to a reference output signal generated by the voltage amplifier in an offset-amplified gain.

Example 17: The method according to any of Examples 14 to 16, wherein the predetermined value represents a target output voltage for a given input voltage.

Example 18: The method according to any of Examples 14 to 17, wherein determining the value indicative of the input offset comprises comparing a reference output signal generated in baseline gain with a reference output signal generated in an offset-amplified gain.

Example 19: The method according to any of Examples 14 to 18, wherein determining the value indicative of the input offset comprises processing reference output signals generated by the voltage amplifier in two or more offset-amplified gains.

Example 20: The method according to any of Examples 14 to 19, comprising: setting a voltage amplifier to a baseline gain, wherein in the baseline gain the voltage amplifier is operable to generate a baseline reference output signal; setting the voltage amplifier to an offset-amplified gain, wherein in the offset-amplified gain the voltage amplifier is operable to generate an offset-amplified reference output signal; and determining the value indicative of input offset at least partially based on the baseline reference output signal and the offset-amplified reference output signal.

Example 21: The method according to any of Examples 14 to 20, wherein applying the trim setting comprises providing the trim setting to a trim input of the voltage amplifier.

Example 22: The method according to any of Examples 14 to 21, wherein a logic circuit to control operation of the voltage amplifier in the one or more selectable gains and apply the trim settings to the voltage amplifier is on-chip with the voltage amplifier.

Example 23: The method according to any of Examples 14 to 22, comprising: allowing the voltage amplifier to settle in the baseline gain before setting it to the offset-amplified gain; and allowing the voltage amplifier to settle in the offset-amplified gain before determining the input offset.

Example 24: The method according to any of Examples 14 to 23, comprising: iteratively adjusting the trim setting over multiple cycles of measurement and compensation until the input offset is reduced below a predetermined threshold.

Example 25: The method according to any of Examples 14 to 24, comprising: gathering reference output signals respectively generated by the voltage amplifier in the baseline gain and the offset-amplified gain; determining the input offset of the voltage amplifier at least partially based on the gathered reference output signals; and providing the determined output offset to an offset compensation circuit.

Example 26: The method according to any of Examples 14 to 25, wherein: operating the voltage amplifier in an offset-amplified gain comprises activating a switch in a feedback network coupled to the voltage amplifier; and operating the voltage amplifier in a baseline gain comprises deactivating the switch in the feedback network.

Example 27: The method according to any of Examples 14 to 26, wherein: operating the voltage amplifier in an offset-amplified gain comprises activating a first switch and deactivating an optional second switch in a feedback network; and operating the voltage amplifier in a baseline gain comprises deactivating the first switch and activating the optional second switch.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a voltage amplifier having selectable gain; and
a logic circuit to:
determine a value indicative of input offset of the voltage amplifier based at least partially on one or more reference output signals generated by the voltage amplifier in at least one of the selected gains; and
apply a trim setting to the voltage amplifier, the trim setting corresponding to the determined value indicative of input offset.

2. The apparatus of claim 1, wherein the voltage amplifier includes an input to receive the trim setting applied by the logic circuit.

3. The apparatus of claim 1, wherein the logic circuit to determine the value indicative of the input offset by processing reference output signals generated by the voltage amplifier in two or more offset-amplified gains.

4. The apparatus of claim 1, wherein the logic circuit to determine the value indicative of the input offset by comparing a reference output signal generated in a baseline gain with a reference output signal generated in an offset-amplified gain.

5. The apparatus of claim 1, wherein the logic circuit to determine the value indicative of the input offset at least partially based on a comparison of a predetermined value to a reference output signal generated by the voltage amplifier in an offset-amplified gain.

6. The apparatus of claim 5, wherein the predetermined value represents a target output voltage for a given input voltage.

7. The apparatus of claim 1, wherein the logic circuit is on-chip with the voltage amplifier.

8. The apparatus of claim 1, wherein the voltage amplifier comprises:
a switch;
a resistor network operatively coupled to the switch; and
an op-amp alternately operable in a baseline gain and an offset-amplified gain responsive to a state of the switch;
wherein the logic circuit to:
set the switch in a first state to place the voltage amplifier in the offset-amplified gain; and
set the switch in a second state to place the voltage amplifier in the baseline gain, the second state different than the first state.

9. The apparatus of claim 1, wherein the voltage amplifier comprises:
a feedback network comprising a first switch and an optional second switch;
a resistor network operatively coupled to the first switch and the optional second switch; and
an op-amp operable in a baseline gain and an offset-amplified gain responsive to a state of the feedback network,
wherein the logic circuit to:
activate the first switch and deactivate the optional second switch to place the voltage amplifier in the offset-amplified gain; and
deactivate the first switch and activate the optional second switch to place the voltage amplifier in the baseline gain.

10. The apparatus of claim 1, wherein the logic circuit and voltage amplifier are integrated on-chip.

11. The apparatus of claim 1, wherein the logic circuit determines the trim setting to reduce a difference between an output signal of the voltage amplifier and a target value.

12. A method, comprising:
operating a voltage amplifier in one or more selectable gains; and
applying a trim setting to the voltage amplifier, the trim setting corresponding to a value indicative of input offset of the voltage amplifier, the value determined at least partially based on reference output signals generated by the voltage amplifier in the one or more selectable gains.

13. The method of claim 12, comprising:
determining the value indicative of input offset of the voltage amplifier at least partially based on one or more of the reference output signals generated by the voltage amplifier in one or more selectable gains.

14. The method of claim 13, wherein determining the value indicative of the input offset comprises comparing a predetermined value to a reference output signal generated by the voltage amplifier in an offset-amplified gain.

15. The method of claim 13, wherein determining the value indicative of the input offset comprises comparing a reference output signal generated in baseline gain with a reference output signal generated in an offset-amplified gain.

16. The method of claim 13, wherein determining the value indicative of the input offset comprises processing reference output signals generated by the voltage amplifier in two or more offset-amplified gains.

17. The method of claim 12, comprising:
setting a voltage amplifier to a baseline gain, wherein in the baseline gain the voltage amplifier is operable to generate a baseline reference output signal;
setting the voltage amplifier to an offset-amplified gain, wherein in the offset-amplified gain the voltage amplifier is operable to generate an offset-amplified reference output signal; and
determining the value indicative of input offset at least partially based on the baseline reference output signal and the offset-amplified reference output signal.

18. The method of claim 12, wherein applying the trim setting comprises providing the trim setting to a trim input of the voltage amplifier.

19. The method of claim 12, wherein a logic circuit to control operation of the voltage amplifier in the one or more selectable gains and apply the trim settings to the voltage amplifier is on-chip with the voltage amplifier.

20. The method of claim 12, comprising:
gathering reference output signals respectively generated by the voltage amplifier in a baseline gain and an offset-amplified gain;
determining the input offset of the voltage amplifier at least partially based on the gathered reference output signals; and
providing the determined value indicative of input offset to an offset compensation circuit.
